(19) United States
(12) Patent Application Publication
(10) Pub. No.: US 2010/0304106 A1
(43) Pub. Date: Dec. 2, 2010

(54) GAS BARRIER LAMINATE FILM AND METHOD OF PRODUCING GAS BARRIER LAMINATE FILM

(75) Inventors: NOBUHIKO TAKANO, KANAGAWA (JP); TOMOYUKI KIKUCHI, KANAGAWA (JP)

Correspondence Address: YOUNG & THOMPSON, 209 Madison Street, Suite 500, Alexandria, VA, 22314, US

(73) Assignee: FUJIFILM CORPORATION, TOKYO (JP)

(21) Appl. No.: 12/788,515

(22) Filed: May 27, 2010

(30) Foreign Application Priority Data
May 29, 2009 (JP) 2009-130277

(51) Int. Cl. B32B 7/02; B05D 1/36; C23C 16/00; B05D 3/06; B05D 3/02; C23C 14/34

(52) U.S. Cl. 428/216; 427/419.7; 427/419.5; 427/255.29; 427/508; 427/384; 204/192.15

(57) ABSTRACT

A gas barrier laminate film including an organic compound layer and an oxide inorganic compound layer and having both excellent gas barrier properties and durability. The gas barrier laminate film comprises an organic compound layer, a silicon atom-containing compound layer on the organic compound layer, and an inorganic compound oxide layer on the silicon atom-containing compound layer.

### BACKGROUND OF THE INVENTION

The present invention relates to a gas barrier laminate film formed of a plurality of superposed films and particularly to a low-cost gas barrier laminate film having excellent gas barrier properties and a method of producing this gas barrier laminate film.

A gas barrier layer is formed not only in such positions or parts as require moisture resistance in various apparatuses and devices including optical devices, displays such as liquid-crystal displays and organic EL displays, semiconductor manufacturing apparatuses, and thin-film solar cells, but also in packaging materials used to package food, clothing, electronic components, and the like. A gas barrier film having a gas barrier layer formed on a plastic film substrate made of, for example, PET is used in various applications including those mentioned above.

Such gas barrier films known in the art include those formed of various materials such as silicon nitride, silicon oxide, silicon oxynitride and aluminum oxide.

Also known is a gas barrier laminate film as described above that is formed of a plurality of layers including an organic compound layer and an inorganic compound layer to provide still higher gas barrier properties (laminate type gas barrier film).

For example, JP 2005-104025 A describes a gas barrier laminate film (laminate film possessing gas barrier properties) comprising at least one inorganic layer formed of a metal oxide of a metal such as silicon, aluminum, titanium, zirconium, and tin formed on a base material film and a layer containing at least one polysilsesquioxane-containing layer formed on this inorganic layer.

The gas barrier laminate film described in JP 2005-104025 A has excellent flexibility and heat resistance achieved in addition to gas barrier properties by compensating for defects of the inorganic layer with polysilsesquioxane.

JP 2006-123307 A describes a gas barrier laminate film comprising a plastic film, a resin layer containing poly(organo)silsesquioxane formed on the plastic film, and an inorganic compound layer formed of one of silicon oxide, silicon oxynitride, silicon oxycarbide, silicon carbide, silicon nitride, and silicon dioxide on the resin layer.

The gas barrier laminate film described in JP 2006-123307 A has an silicon-based inorganic compound layer formed on such a resin layer to provide a dense layer at the interface between these two layers, thereby achieving improved barrier properties against oxygen and steam.

### SUMMARY OF THE INVENTION

Where a high level of gas barrier properties against steam, oxygen, etc. is required as with sealing films for organic EL devices and solar cells, one often uses a method whereby a smooth layer is disposed on a substrate to provide a smooth surface for an inorganic compound layer having gas barrier properties to be formed thereon.

A gas barrier laminate film provided with such a smooth layer, which is mostly an organic compound layer, and an inorganic compound layer disposed thereon is known to exhibit a high level of barrier properties against steam and oxygen.

Among inorganic compounds known to exhibit excellent gas barrier properties is silicon nitride. A silicon nitride film has excellent barrier properties because of a high density. On the other hand, where a silicon nitride film is formed by plasma-enhanced CVD, as is often the case, the feed gases used are silane gas and ammonia gas (or liquid organosilane and liquid ammonia are vaporized for the purpose), and their use is accompanied with concern about safety.

Other inorganic compounds known to exhibit gas barrier properties include such inorganic compound oxides as silicon oxide and aluminum oxide. A film formed of an inorganic compound oxide can be safely produced by introducing oxygen, which is an advantage over a silicon nitride film.

However, where the inorganic compound layer formed on the organic compound layer is an inorganic compound oxide layer in a gas barrier laminate film comprising an inorganic compound layer formed on an organic compound layer, desired gas barrier properties often cannot be obtained even though a smooth organic compound layer is provided.

An object of the present invention is to overcome the above problems associated with the prior art and provide a gas barrier laminate film, having excellent gas barrier properties, boasting an excellent adhesion between the organic compound layer and the inorganic compound layer, permitting consistent production, and available at low-cost in a gas barrier laminate film comprising an inorganic compound oxide layer as an inorganic compound layer formed on an organic compound layer, and a method of producing this gas barrier laminate film.

To achieve the above object, the gas barrier laminate film of the invention comprises at least one combination of a 0.1 μm to 3 μm thick organic compound layer, a 0.005 μm to 0.3 μm thick silicon atom-containing compound layer formed on the organic compound layer, and an inorganic compound oxide layer formed on the silicon atom-containing compound layer.

In the gas barrier laminate film of the invention as described above, it is preferable that the silicon atom-containing compound layer contains polysilsesquioxane, the polysilsesquioxane contains (meth)acryl group, the polysilsesquioxane comprises one or more of a cage structure, a ladder structure, a random structure, and a cleaved structure.

Alternatively, it is preferable that the silicon atom-containing compound layer contains a compound expressed by SiOₓ and contains 10% or less of impurities by atomic composition.

The method of producing a gas barrier laminate film according to the invention comprises forming a 0.1 μm to 3 μm-thick organic compound layer on a substrate, forming a 0.005 μm to 0.3 μm-thick silicon atom-containing compound layer on the organic compound layer, and forming an inorganic compound oxide layer on the silicon atom-containing compound layer.

In the method of producing a gas barrier laminate film according to the invention, the silicon atom-containing compound layer preferably contains polysilsesquioxane, or the silicon atom-containing compound layer preferably contains a compound expressed by SiOx and contains 10% or less of impurities by atomic composition.

Preferably, the inorganic compound oxide layer is formed by CVD using at least an inactive gas, oxygen gas, and tetraethoxysilane or hexamethyldisiloxane as feed gases, wherein the CVD is atmospheric CVD, or, alternatively, the inorganic compound oxide layer is formed by sputtering using a target formed of silicon or a silicon compound and accompanied by introduction of oxygen gas.

Preferably, the silicon atom-containing compound layer is formed by applying a liquid containing a silicon atom-containing compound onto the organic compound layer and curing the liquid by one or more of irradiation with ultraviolet light, exposure to radiation, and heating, and a long length of substrate is passed over a peripheral surface of a cylindrical drum and transported in a longitudinal direction as the substrate undergoes, sequentially, formation of the organic compound layer thereon by using an organic compound layer forming means provided opposite the peripheral surface of the drum, formation of the silicon atom-containing compound layer by using a silicon atom-containing compound layer forming means provided downstream of the organic compound layer forming means, and formation of an inorganic compound oxide layer by using a film deposition means provided downstream of the silicon atom-containing compound layer forming means and using vapor-phase film deposition technique, the organic compound layer being preferably formed by flash evaporation.

According to the invention, in the gas barrier laminate film provided with an inorganic compound oxide layer permitting safe production, a silicon atom-containing compound layer such as one formed of polysilsesquioxane formed on an organic compound layer, which is provided to compensate for the asperity and strains of the substrate in order to planarize the film deposition surface for the inorganic compound layer, prevents the film deposition surface for the inorganic compound oxide layer from being damaged when the inorganic compound oxide layer is formed.

Thus, in the gas barrier laminate film comprising an organic compound layer and an inorganic compound layer, the gas barrier laminate film of the invention allows an inorganic compound oxide layer to be formed on a highly smooth film deposition surface, so that decrease of gas barrier properties (against stream and oxygen) due to a roughened film deposition surface can be prevented, and the organic compound layer and the inorganic compound layer can both sufficiently exhibit their intended performances, that is, a gas barrier laminate film having excellent gas barrier properties can be produced in a consistent manner.

### BRIEF DESCRIPTION OF THE DRAWINGS

FIG. 1 is a schematic view showing an embodiment of the gas barrier laminate film of the present invention.

FIG. 2 is a schematic view showing a configuration of an embodiment of a substrate used in the gas barrier laminate film of the present invention.

FIG. 3 is a schematic view showing an embodiment of the production apparatus for implementing the gas barrier laminate film production method of the present invention.

FIG. 4 is a view schematically showing an example of a section of the production apparatus shown in FIG. 1 for forming an organic compound layer.

### DETAILED DESCRIPTION OF THE INVENTION

Now, the method for producing a gas barrier laminate film according to the present invention and the gas barrier laminate film thereby produced will be described in detail by referring to the preferred embodiments shown in the accompanying drawings.

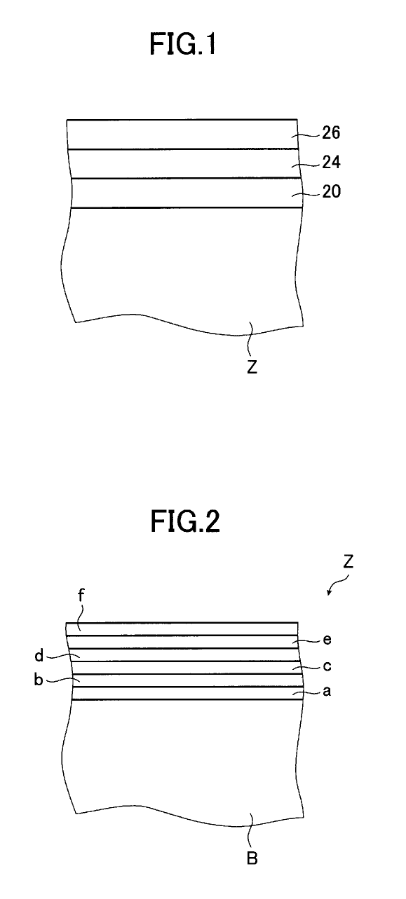

FIG. 1 is a schematic view showing an embodiment of the gas barrier laminate film of the present invention.

The gas barrier laminate film shown in FIG. 1 is produced by forming an organic compound layer 20 on the substrate Z, forming a silicon atom-containing compound layer 24 on the organic compound layer 20, and forming an inorganic compound oxide layer 26 on the silicon atom-containing compound layer 24.

In the description to follow, the organic compound layer 20 is referred to also as organic layer 20, the silicon atom-containing compound layer 24 as silicon-containing layer 24, and the inorganic compound oxide layer 26 as oxide layer 26 for the purpose of the invention.

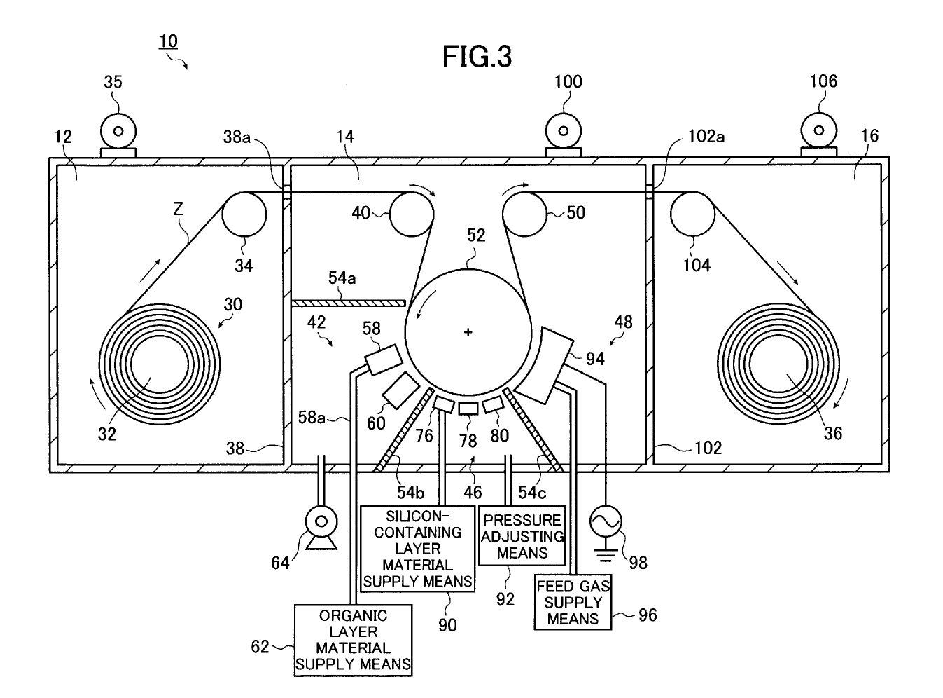

A preferred example of the substrate Z on which the gas barrier laminate film is to be formed according to the invention is a long length of a flexible sheet substrate as shown in FIG. 3 as described later.

According to the present invention, the substrate Z is not limited to the substrate Z in the form of a long sheet and may be any of various articles (members/base materials) including a sheet material cut into a given length (cut sheet), optical devices such as lenses and optical filters, photoelectric transducers such as organic EL devices and solar cells, and display panels such as liquid-crystal displays and electronic paper.

The material of the substrate is also not particularly limited, and one may use various materials permitting formation of the organic layer 20. The substrate may be made of any of organic materials such as plastic films (resin films) or of inorganic materials such as metals and ceramics.

The present invention is advantageously used to produce a gas barrier film as in the illustrated case, making it preferable to use sheet substrates (plastic films) made of such organic substances as polyethylene terephthalate (PET), polyethylene naphthalate (PEN), polyethylene, polypropylene, polystyrene, polyamide, polyvinyl chloride, polycarbonate, polyacrylonitrile, polyimide, polyacrylate, and polymethacrylate.

The substrate Z to be used in the present invention may be one formed of a base material such as a plastic film or a lens having such layers (films) formed thereon to impart various functions as, for example, a protective layer, an adhesive layer, a light-reflecting layer, a light-shielding layer, a planarizing layer, a buffer layer, and a stress-relief layer.

The substrate Z may be one having a single layer formed on a base material or one having a plurality of layers such as layers a to f formed on a base material B as conceptually shown in FIG. 2.

In the substrate Z having a film of two or more layers formed on the base material B, any three consecutive layers may be the gas barrier laminate film of the invention. That is, any three consecutive layers of the layers on the substrate Z may form the gas barrier laminate film of the invention.

More specifically in FIG. 2, for example, the layers a to c may be the organic layer 20, the silicon-containing layer 24, and the oxide layer 26, respectively; or the layers d to f may be the organic layer 20, the silicon-containing layer 24, and the oxide layer 26, respectively; or the layers c to e may be the organic layer 20, the silicon-containing layer 24, and the oxide layer 26, respectively. Alternatively, in FIG. 2, the layers a to c may be the organic layer 20, the silicon-containing layer 24, and the oxide layer 26, respectively, and the layers d to f may also be the organic layer 20, the silicon-containing layer 24, and the oxide layer 26, respectively.

According to the production method of the invention, therefore, the substrate Z having the gas barrier laminate film of the invention may be further formed with another gas barrier laminate film of the invention.

The organic layer (organic compound layer) 20 in the gas barrier laminate film of the invention is a layer (so called planarizing layer) provided to compensate for or absorb the asperity, strains, waviness, etc. of the surface of the substrate Z and planarize the film deposition surface on which the oxide layer 26 is to be formed.

In addition to the function of planarizing layer, the organic layer 20 may have other functions to serve as protective layer, adhesion layer, light-reflecting layer, light-shielding layer, buffer layer, and stress-relief layer.

The material of the organic layer 20 according to the invention is not specifically limited and may be selected as appropriate from a variety of organic compounds capable of compensating for the asperity or other properties of the substrate Z and providing a sufficiently smooth surface (film deposition surface for the silicon-containing layer 24).

The organic compound used to form the organic layer 24 include polymers such as (meth)acrylic resin, polyester, methacrylic acid—maleic acid copolymer, polystyrene, transparent fluororesin, polyimide, fluorinated polyimide, polyamide, polyamideimide, polyetherimide, cellulose acylate, polyurethane, polyetherketone, polycarbonate, polycarbonate modified with fluorene ring, polycarbonate modified with an alicycle, and polyester modified with fluorene ring. These high-molecular compounds or polymers composed of monomer mixtures are obtained by polymerizing monomer mixtures.

A preferred polymer for forming the organic layer 20 is an acrylic resin or a methacrylic resin having a polymer composed of an acrylate and/or methacrylate monomer as a major component.

Specific examples of acrylates and methacrylates preferably used for forming the organic layer 20 according to the invention are given below only as illustrative but not limitative examples of the present invention.

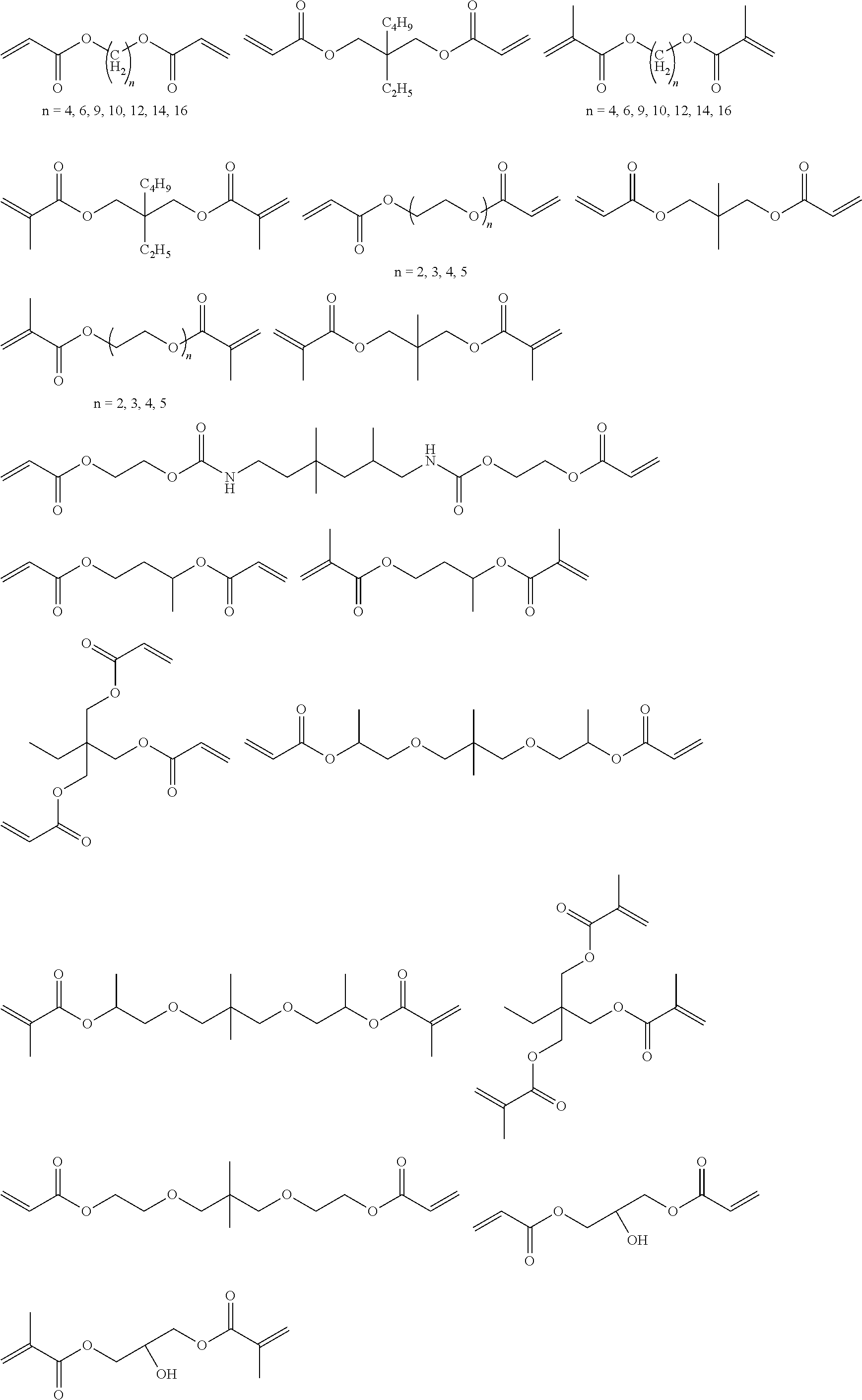

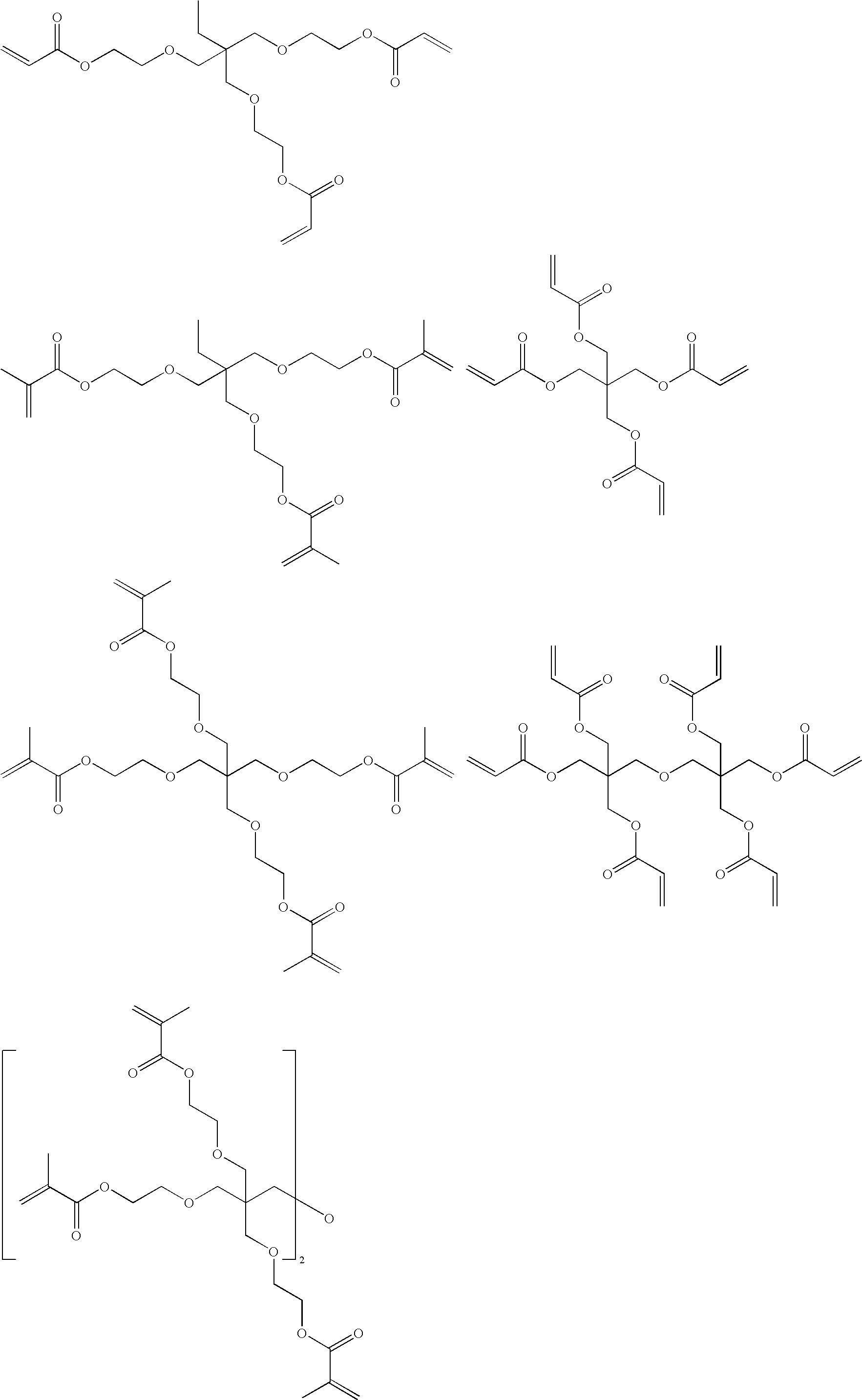

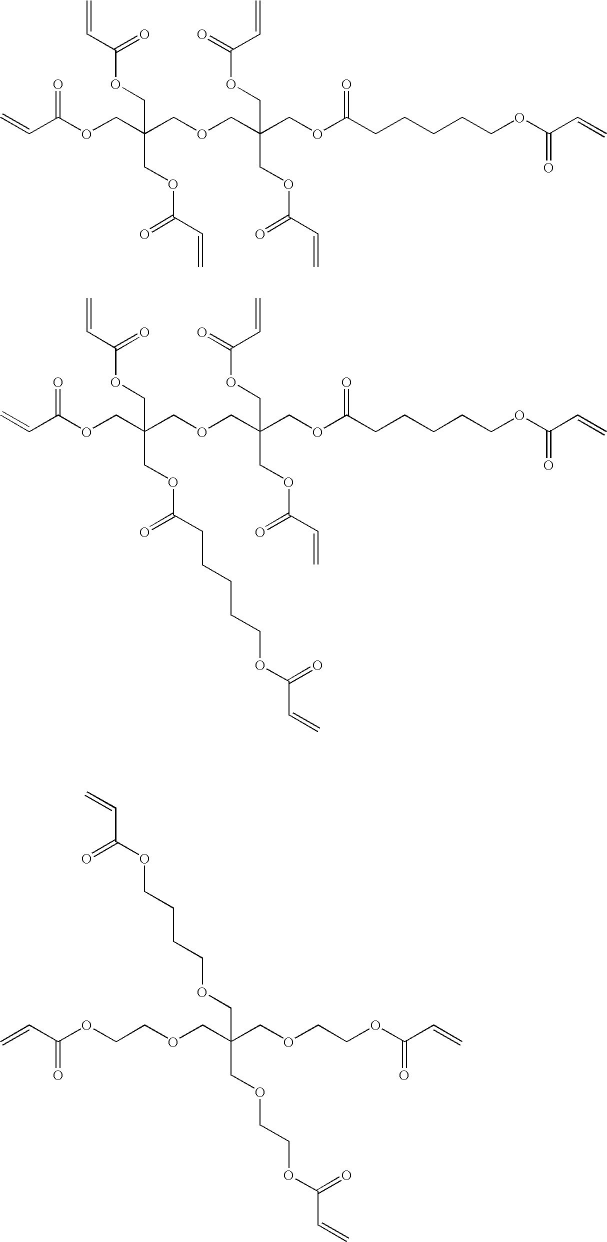

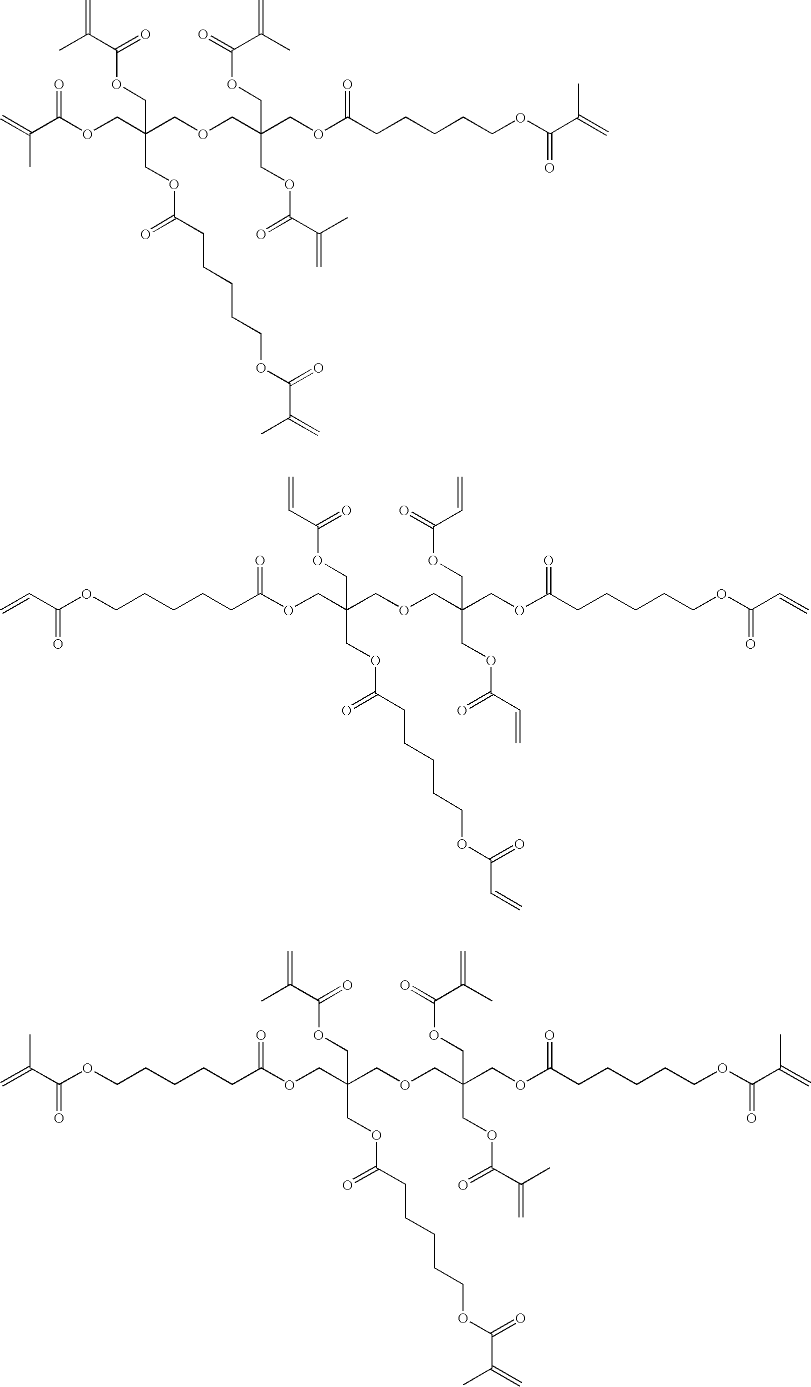

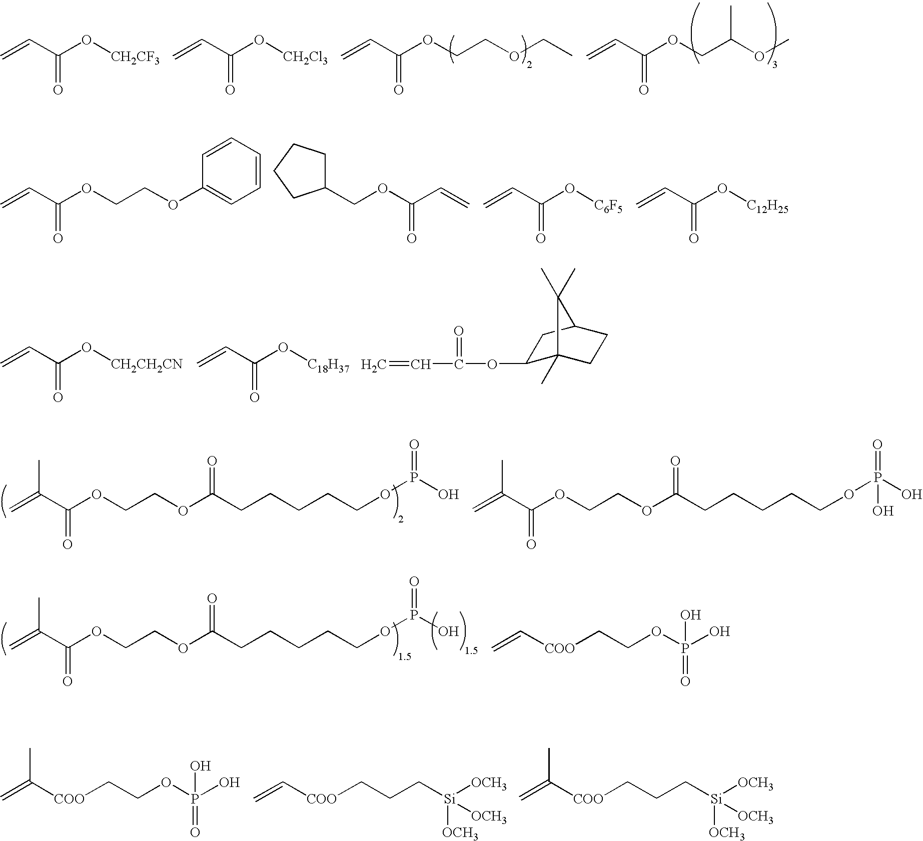

According to the invention, the organic layer 20 has a thickness of 0.1 μm to 3 μm.

When the organic layer 20 has a thickness of less than 0.1 μm, it fails to compensate for the asperity or other properties of the substrate Z and provide a sufficiently smooth surface, among other drawbacks.

When the organic layer 20 has a thickness of greater than 3 μm, the whole film thickness becomes unnecessarily great, the flexibility decreases, and the optical transparency decreases, among other disadvantages.

The organic layer 20 preferably has a thickness of 0.4 μm to 0.8 μm.

A thickness of the organic layer 20 in the above range allows a gas barrier laminate film having excellent gas barrier properties to be obtained while maintaining favorable mechanical characteristics and optical properties, among other advantages.

Although the surface roughness of the organic layer 20 is not specifically limited, the gas barrier properties improve as the surface smoothness increases. A preferable mean surface roughness Ra is 1 nm or less, most preferably 0.5 nm or less.

When the organic layer 20 has a surface roughness in that range, favorable results will be obtained such as excellent gas barrier properties.

According to the invention, the organic layer 20 may be formed in any method as appropriate including any known method used for forming a layer (film) of an organic compound.

One may preferably use any of coating methods as appropriate including
a method whereby a coating material is prepared by dissolving an organic compound forming the organic layer 20 and applied to the surface of the substrate Z and dried; a method whereby the monomer to form the organic layer 20 is dissolved together with a polymerization initiator to prepare a coating material, which is applied to the surface of the substrate Z and dried, and then exposed to ultraviolet light, electron beams, or heat to polymerize the monomer; and a method, whereby an organic compound and a monomer to form the organic layer 20 are dissolved to prepare a coating material, which is evaporated, whereupon the resultant vapor is caused to attach to the substrate Z, then cooled and condensed to form a liquid film, which is exposed to ultraviolet light or electron beams for curing (so-called flash evaporation technique).

Flash evaporation technique, in particular, may be advantageously used.

The gas barrier laminate film according to the invention has a silicon-containing layer (silicon atom-containing compound layer) 24 formed on the surface of the organic layer 20.

The silicon-containing layer 24 contains a silicon atom-containing compound and, more specifically, contains a silicon atom-containing compound as a major component, such as those expressed by general formulae SiOₓC_{y}, SiOₓ, SiOCₓN_{y}, SiCₓ, SiNₓC_{y}, SiNₓ, SiOₓN_{y}, and RSiO_{3/2}. For example, the silicon-containing layer 24 may be a layer formed by preparing a coating material containing particles of such compounds dispersed or dissolved therein and applying the coating material onto the surface of the organic layer 20, which coating material is allowed to dry and cure.

A preferred example of the silicon-containing layer 24 is a layer containing SiOₓ (silica) as a major component.

The silicon-containing layer 24 may, for example, be preferably formed using PHPS (perhydropolysilazane). PHPS is a viscous oligomer having a basic structure comprising a unit of —(SiH₂NH)—. PHPS is dissolved, where necessary, in a solvent and applied onto the surface, followed by heating to remove N and H, thus trapping O atoms from the air instead to form the siloxane bond (Si—O bond). Thus can be formed a layer containing SiOₓ as a major component.

Alternatively, a layer containing SiOₓ as a major component may be formed by preparing a coating material containing particles of SiOₓ dispersed therein and applying the coating material onto the surface of the organic layer 20, followed by drying and curing.

The diameter of SiOₓ particles is preferably 50 nm or less, more preferably 15 nm or less to reduce the adverse effects of light scattering in the gas barrier laminate film or for other reasons. The same applies to other silicon atom-containing compounds than SiOₓ.

The silicon-containing layer 24 containing SiOₓ as a major component preferably contains 10% or less of impurities by atomic composition such as C, H, and N.

Where the silicon-containing layer 24 containing SiOₓ as a major component contains 10% or less of impurities by atomic composition, favorable results will be obtained such as formation of a layer having an increased film density and hence less pores, among other advantages.

More preferable examples of the silicon-containing layer 24 include one containing polysilsesquioxane, in particular one containing polysilsesquioxane as a major component.

Poly(organo)silsesquioxane is a compound containing silsesquioxane in the structural unit.

“Silsesquioxane” is a compound expressed by a general formula RSiO_{3/2} and generally denotes polysiloxane, a synthesized product obtained by subjecting to hydrolysis-polycondensation a compound expressed by a general formula RSiX₃, where R is hydrogen atom, alkyl group, alkenyl group, aryl group, aralkyl group, (meth)acryl group ((meth)acryloyl group), etc., and X is halogen, alkoxy group, etc.

Known typical molecular arrangements of silsesquioxane include those having an amorphous structure, a ladder structure, a cage structure, and a partially cleaved cage structure (cage structure having one silicon atom missing or cage structure having some of the silicon-oxygen bonds severed).

Polysilsesquioxane having an amorphous structure or a ladder structure exists in the silicon-containing layer 24 in the form of polymer having silsesquioxane as monomer unit. Polysilsesquioxane having a cage structure or a partially cleaved cage structure exists in the silicon-containing layer 24 in a form comprising a plurality of silsesquioxane having one structure.

Among the silsesquioxane described above, particularly preferred are polysilsesquioxane having a cage structure and polysilsesquioxane having a partially cleaved cage structure according to the invention.

Examples of silsesquioxane having a cage structure include silsesquioxane expressed by chemical formula [RSiO_{3/2}]₈ and represented by general formula (1) below, silsesquioxane expressed by chemical formula [RSiO_{3/2}]₁₀ and represented by general formula (2) below, silsesquioxane expressed by chemical formula [RSiO_{3/2}]₁₂ and represented by general formula (3) below, silsesquioxane expressed by chemical formula [RSiO_{3/2}]₁₄ and represented by general formula (4) below, and silsesquioxane expressed by chemical formula [RSiO_{3/2}]₁₆ and represented by general formula (5) below.

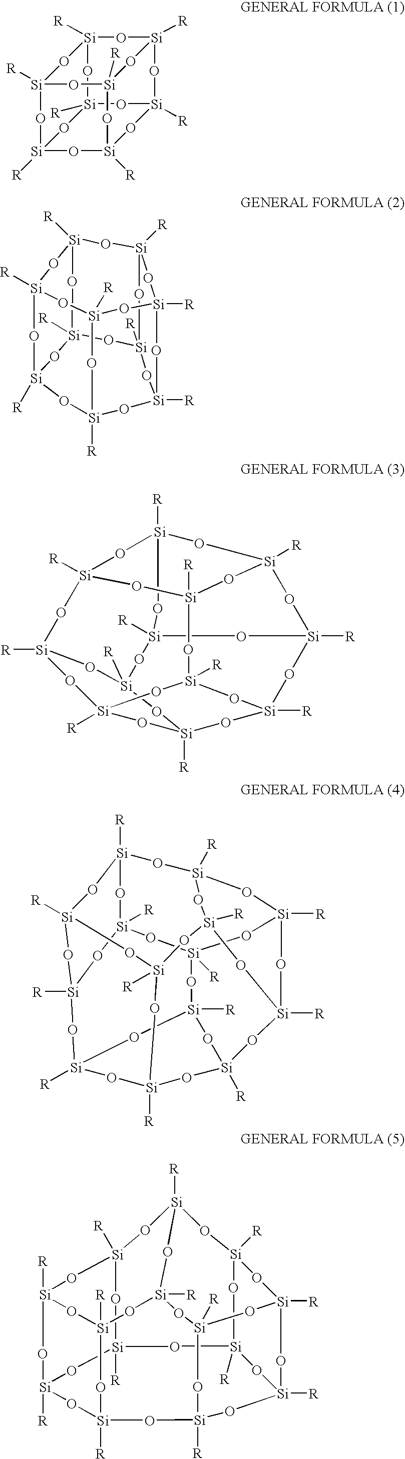

In silsesquioxane expressed by [RSiO_{3/2}]ₙ, n is an integer from 6 to 20, preferably 8, 10 or 12, or most preferably, either n is 8 or n is 8, 10 and 12 such that the silsesquioxane is a mixture.

Preferred examples of silsesquioxane having a cage structure and expressed by [RSiO_{3/2}]₇(O_{1/2}H)₂₊ₘ (n is any of integers 6 to 20; m is 0 or 1) where some of the silicon-oxygen bonds are partially cleaved include trisilanol represented by general formula (1) with partial cleavage; silsesquioxane expressed by chemical formula [RSiO_{3/2}]₇(O_{1/2}H)₃ and represented by general formula (6); silsesquioxane expressed by chemical formula [RSiO_{3/2}]₈(O_{1/2}H)₂ and represented by general formula (7); and silsesquioxane expressed by chemical formula [RSiO_{3/2}]₈(O_{1/2}H)₂ and represented by general formula (8).

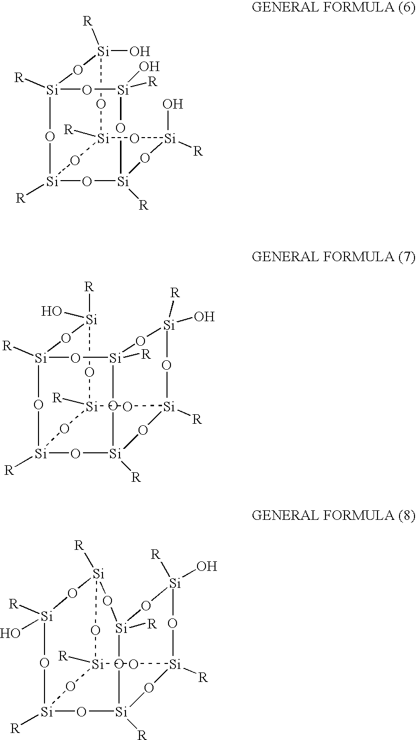

R in silsesquioxane, particularly R in general formulae 1 to 8 above is exemplified by hydrogen atom, (meth)acryl group, saturated hydrocarbon group having 1 to 20 carbon atoms, alkenyl group having 2 to 20 carbon atoms, aralkyl group having 7 to 20 carbon atoms, and aryl group having 6 to 20 carbon atoms. R is preferably a polymerizable functional group permitting polymerization reaction.

Examples of saturated hydrocarbon group having 1 to 20 carbon atoms include methyl group, ethyl group, n-propyl group, i-propyl group, butyl group (n-butyl group, i-butyl group, t-butyl group, sec-butyl group, etc.), pentyl group (n-pentyl group, i-pentyl group, neo-pentyl group, cyclo-pentyl group, etc.), hexyl group (n-hexyl group, i-hexyl group, cyclohexyl group, etc.), heptyl group (n-heptyl group, i-heptyl group, etc.) octyl group (n-octyl group, i-octyl group, t-octyl group, etc.), nonyl group (n-nonyl group, i-nonyl group, etc.), decyl group (n-decyl group, i-decyl group, etc.), undecyl group (n-undecyl group, i-undecyl group, etc.), and dodecyl group (n-dodecyl group, i-dodecyl group, etc.).

Considering a balance between melt fluidity, flame resistance, and ease of handling in the process of forming the silicon-containing layer 24, R is preferably a saturated hydrocarbon having 1 to 16 carbon atoms, most preferably a saturated hydrocarbon having 1 to 12 carbon atoms.

Examples of alkenyl group having 2 to 20 carbon atoms include an acyclic alkenyl group and cyclic alkenyl group. Examples thereof include vinyl group, propenyl group, butenyl group, pentenyl group, hexenyl group, cyclohexenyl group, cyclohexenyl ethyl group, norbornenyl ethyl group, heptenyl group, octenyl group, nonenyl group, decenyl group, undecenyl group, and dodecenyl group.

Considering a balance between melt fluidity, flame resistance, and ease of handling in the process of forming the silicon-containing layer 24, R is preferably an alkenyl group having 2 to 16 carbon atoms, most preferably an alkenyl group having 2 to 12 carbon atoms.

Examples of aralkyl group having 7 to 20 carbon atoms include benzyl group and phenethyl group, or benzyl group and phenethyl group with single or multiple substitution in alkyl groups having 1 to 13 carbon atoms, preferably 1 to 8 carbon atoms.

Examples of aryl group having 6 to 20 carbon atoms include phenyl group and tolyl group or phenyl group, tolyl group, and xylyl group substituted with an alkyl group having 1 to 14 carbon atoms, preferably 1 to 8 carbon atoms.

Silsesquioxane having a cage structure described above may be silsesquioxane compounds as provided by, for example, Sigma-Aldrich Corporation, Hybrid Plastics, Inc. and Chisso Corporation or a silsesquioxane compound synthesized according to the description given in, for example, Journal of American Chemical Society, Vol. 111, page 1741, the 1989 edition.

The SQ Series provided by Toagosei Co., Ltd. may also be favorably used as silsesquioxane for the purpose. Silsesquioxane containing a (meth)acryl group in R may also be favorably used for easy curing of the film achieved by exposure to ultraviolet light and an adjustable film hardness, among other advantages. In this regard, the AS-SQ in the SQ Series mentioned above may be favorably used.

A partially cleaved cage structure of polysilsesquioxane cage structure denotes a compound having a three or less Si—OH produced as Si—O—Si bond is cleaved in one cage unit expressed by a chemical formula [RSiO_{3/2}]₈ or a compound having a closed cage structure expressed by a chemical formula [RSiO_{3/2}]₈ having one or fewer missing Si atoms.

Polysilsesquioxane is preferably mixed for use with a binder that is capable of reacting with a functional group R. Binders capable of such reaction include thermosetting resins and radiation curable resins.

Thermosetting resins that may be used include epoxy resins.

Epoxy resins here include those of polyphenol type, bisphenol type, halogenated bisphenol type, and novolac-type.

Epoxy resins used for the purpose may be cured using any of known curing agents. Curing agents that may be used include amins, polyaminoamides, acids, acid anhydrides, imidazoles, mercaptans, and phenol resins. Considering such factors as solvent resistance, optical properties, and thermal characteristics, acid anhydrides and polymers comprising an acid anhydride structure or aliphatic amines are preferably used, and acid anhydrides and polymers comprising an acid anhydride structure are most preferably used. Any of known appropriate curing catalysts such as tertiary amines and imidazoles is preferably added in an appropriate amount.

Radiation curable resins are resins in which cure proceeds by exposure to radiation such as ultraviolet light and electron beams and specifically are resins that comprise an unsaturated double bond such as (meth)acryl group and vinyl group in a molecule or a unitary structure. Among others, acryl resins comprising an acryl group are preferred.

The radiation curable resin may be one kind of resin or several kinds of resins mixed for use and preferably an acryl resin or resins comprising two or more acryl groups in a molecule or a unitary structure. Examples of such polyfunctional acrylate resins include but are not limited to dipentaerythritol hexaacrylate, pentaerythritol tetraacrylate, urethane acrylate, ester acrylate, and epoxyacrylate.

Where an ultraviolet cure technique is used, the above-mentioned radiation curable resins are added with an appropriate amount of a known photoreaction initiator.

Where the silicon-containing layer 24 of the gas barrier laminate film of the invention contains silsesquioxane, the above combination of silsesquioxane and binder is preferably a copolymer formed by silsesquioxane having a polymerizable functional group and a polyfunctional monomer.

The combination of a polymerizable functional group R of silsesquioxane and a copolymerizable binder is preferably such that R is an acryl group and the binder capable of such reaction is a polyfunctional acrylate. It is also preferable that R is an epoxy group and the binder capable of the reaction is a polyfunctional epoxy.

The above epoxy resins and radiation curable resins may be added with an alkoxysilane hydrolysate or a silane coupling agent to intensify the interactions with silsesquioxane.

The silane coupling agent used preferably has a hydrolyzable reactive group such as methoxy group, ethoxy group and acetoxy group on one side and epoxy group, vinyl group, amino group, halogen group, and mercapto group on the other. In this case, the silane coupling agent most preferably has a vinyl group having the same reactive group for attachment to the major component resin, examples thereof being KBM-503 and KBM-803 provided by Shin-Etsu Chemical Co., Ltd. and A-187 provided by Nippon Unicar Co., Ltd. These agents are preferably added in an amount of 0.2 to 3 mass %.

Where the silicon-containing layer 24 of the gas barrier laminate film of the invention contains polysilsesquioxane, polysilsesquioxane is contained in the silicon-containing layer 24 preferably in an amount of 50 to 100 wt %, particularly 60 to 90 wt %.

Where polysilsesquioxane is contained in an amount of 50 to 100 wt %, the gas barrier laminate film obtained has good heat resistance and gas barrier properties.

Preferably, polysilsesquioxane may be mixed with another compound such as polyvinyl alcohol to form the silicon-containing layer 24, provided that polysilsesquioxane is contained in an amount within the above range.

Where the silicon-containing layer 24 of the gas barrier laminate film of the invention contains polysilsesquioxane, the silicon-containing layer 24 may be preferably formed by such techniques as coating and flash evaporation described above, which are preferred to vapor-phase deposition techniques such as vapor deposition and plasma-enhanced CVD for the speed at which the silicon-containing layer 24 can be formed and the costs involved, among other reasons. Where the oxide compound layer 26 described later is formed by vacuum deposition, preferred film deposition methods include flash deposition under vacuum and integrated film deposition technique.

By way of example, a coating material containing silsesquioxane, the binder described earlier, etc. is prepared and applied onto the organic layer 20 by flash evaporation or the coating technique described later, followed by drying, exposure to ultraviolet, exposure to electron beams, heating, and the like, to polymerize and cure silsesquioxane, thereby forming the silicon-containing layer 24. Polymerization may be achieved using a plurality of means.

Polymerization (cross-linking) of silsesquioxane may be achieved by any methods as appropriate and preferably by methods employing active energy line through exposure to electron beams, ultraviolet light, etc. for the speed at which a high molecular weight is achieved by polymerization. The active energy line denotes radiation capable of propagating energy by radiating ultraviolet light, X-ray, electron beams, infrared light, microwaves, etc.; the kind and energy used may be selected as appropriate according to the applications intended.

Coating may be effected employing any of various conventional techniques used for forming a film by coating such as roll coating, gravure coating, knife coating, dip coating, curtain flow coating, spray coating, bar coating, and spin coating.

In the gas barrier laminate film of the invention, the silicon-containing layer 24 has a thickness of 0.005 μm to 0.3 μm.

As will be described later, the silicon-containing layer 24 is provided to prevent the surface of the organic layer 20 from being damaged or roughed when forming the oxide layer 26, the layer to be located thereon. The silicon-containing layer 24 having a thickness of less than 0.005 μm fails to protect the organic layer 20 from damage when forming the oxide layer 26 among other disadvantages.

The silicon-containing layer 24 having a thickness of over 0.3 μm increases the costs for manufacturing the gas barrier laminate film (the silicon-containing layer 24 containing silsesquioxane, in particular) and reduces the flexibility thereof, among other disadvantages.

The silicon-containing layer 24 preferably has a thickness of 0.005 μm to 0.05 μm, most preferably 0.005 μm to 0.015 μm.

The silicon-containing layer 24 having a thickness withing the above range yields favorable results such that a gas barrier laminate film having a good flexibility and a good permeability to visual light can be obtained, among others.

Although the surface roughness of the organic layer 24 is not specifically limited, the gas barrier properties improve as the surface smoothness increases as with the organic layer 20. A preferable mean surface roughness Ra is 1 nm or less, most preferably 0.5 nm or less.

The inorganic layer 24 having a surface roughness in that range yields favorable results such as consistently obtained excellent gas barrier properties.

According to the production method of the invention, where deposition of the organic layer 20 and the silicon-containing layer 24 are achieved by coating, a simultaneous dual layer deposition technique may be employed whereby a coating material to form the organic layer 20 and a coating material to form the silicon-containing layer 24 are applied simultaneously, followed by drying and curing.

As described earlier, the organic layer 20 and the silicon-containing layer 24 preferably have a high degree of surface smoothness. On the other hand, where the film deposition is achieved by coating, a thick film allows a good surface smoothness to be obtained.

Accordingly, the simultaneous dual layer deposition is advantageous in achieving a good surface smoothness for both layers, in particular the silicon-containing layer 24.

In the gas barrier laminate film of the invention, the silicon-containing layer 24 is formed thereon with the oxide layer (inorganic oxide compound layer) 26 such as an SiOₓ layer and an AlₓO_{y} layer.

According to the invention, the gas barrier laminate film formed with the organic layer (organic compound layer) 20 and the oxide layer 26 as an inorganic compound layer further comprises the silicon-containing layer 24 between the organic layer 20 and the oxide layer 26, and this configuration results in a gas barrier laminate film having excellent adhesion and heat resistance as well as excellent gas barrier properties.

As described above, a configuration comprising an inorganic compound layer formed on a smooth layer containing an organic compound provided on a substrate is used in applications requiring enhanced gas barrier properties such as sealing films as used in organic EL devices and solar cells.

Where the inorganic compound layer is, for example, a silicon nitride film in the gas barrier laminate film having an organic/inorganic laminate structure, a gas barrier laminate film having a desired performance can be obtained in a relatively consistent manner, although there are safety issues and the like related to the use of silane gas.

Where, on the other hand, the inorganic compound layer is an inorganic compound oxide layer such as a silicon oxide film or an aluminum oxide film in the gas barrier laminate film having an organic/inorganic laminate structure, a gas barrier laminate film obtained often failed to give a desired performance, although safety was not an issue.

The present inventors investigated the causes therefor and found that, where the inorganic compound layer is formed of an oxide in the gas barrier laminate film having an organic/inorganic laminate structure, oxygen radicals occurring during the formation of the inorganic compound layer charge into the organic compound layer in a manner comparable to etching, thereby leaving the surface of the organic compound layer roughened to a significantly reduced smoothness.

Deposition of a gas barrier film formed of an inorganic compound is achieved typically by vapor-phase film deposition technique such as plasma-enhanced CVD and sputtering. According to these deposition techniques, deposition of an oxde film is typically accompanied by introduction of feed gas into the oxide film.

The oxygen gas acts as oxygen radicals to etch the surface of the organic compound layer and thus roughen the surface of the organic compound layer.

Even when film deposition is accomplished without the introduction of oxygen gas, generation of oxygen radicals in the atmosphere is inevitable when an oxide film is formed. Thus, etching by oxygen radicals likewise takes place inevitably.

As described above, the organic compound layer is provided to smooth the deposition surface for the inorganic compound layer and thus maximize the gas barrier properties of the inorganic compound layer.

Should the surface of the organic compound layer be roughened by oxygen radicals in the inorganic compound layer deposition process, it would be the same as when no organic compound layer is provided and the inorganic compound layer is deposited directly on a substrate having a poor surface smoothness, with the result that, in worst cases, the inorganic compound layer is deposited on a deposition surface that is rougher than the substrate surface.

Thus, the gas barrier properties of the gas barrier laminate film decrease considerably.

In contrast, the gas barrier laminate film of the invention comprises the silicon-containing layer 24 having a thickness of 0.005 μm to 0.3 μm formed on the organic layer 20 and the oxide layer 26 exhibiting, principally, gas barrier properties on the silicon-containing layer 24.

According to the study by the present inventors, a significantly high resistance to etching caused by oxygen radicals and an excellent adhesion to the oxide layer 26 (layer formed of an inorganic compound oxide) are observed in the silicon-containing layer 24 (layer formed of a silicon atom-containing compound), among others a layer containing SiOₓ described above and, in particular, a layer containing polysilsesquioxane.

Thus, according to the gas barrier laminate film of the invention, the oxide layer 26 can be formed with a high degree of adhesion on a film deposition surface having a good smoothness so that a gas barrier laminate film having an excellent interlayer adhesion (i.e., endurance) and excellent gas barrier properties of 5×10⁻³ g/[m²·day] or less can be obtained in a consistent manner. Even where polysilsesquioxane, an expensive material, is used for the silicon-containing layer 24, the resultant layer is so thin with a thickness of 0.005 μm to 0.3 μm that it is advantageous in terms of costs.

The oxide layer 26 of the gas barrier laminate film of the invention may be any of various inorganic compound oxide layers exhibiting gas barrier properties (steam barrier properties and oxygen barrier properties) and may specifically be layers formed of inorganic compound oxides (inorganic oxides) expressed by general formulae SiOₓ, SiOₓC_{y}, SiOCₓN_{y}, SiOₓN_{y}, and AlₓO_{y}.

The thickness of the oxide layer 26 is not specifically limited and may be determined as appropriate according to the gas barrier properties required of the gas barrier laminate film, the kind of the oxide layer 26 (material thereof), the layer configuration of gas barrier films with which the gas barrier laminate film is formed, the applications for which the products on which the gas barrier laminate film is formed are used, and the like.

The oxide layer 26 may be formed or deposited by any of known vapor-phase film deposition techniques including but not limited to CVD and sputtering depending on the oxide layer 26 to be formed. The film deposition conditions may also be determined as appropriate according to the kind and film thickness of the oxide layer 26 to be formed.

Thus, CVD techniques that may be used herein may be any known CVD techniques as appropriate including but not limited to CCP (Capacitively Coupled Plasma)—CVD, ICP (Inductively Coupled Plasma)—CVD, microwave CVD, ECR (Electron Cyclotron Resonance)—CVD, barrier discharge DVD under a low pressure or atmospheric pressure, and Cat (Catalytic)—CVD.

When the oxide layer 26 is formed by any of these CVD techniques, preferred is a CVD technique using at least an inactive gas (noble gas, nitrogen gas), oxygen gas, and tetraethoxysilane (TEOS) or hexamethyldisiloxane (HMDSO) as feed gases.

Use of CVD technique employing feed gases as described above yields favorable results because it permits safe deposition of the oxide layer 26 and is preferable because it permits easy procurement of materials.

When the oxide layer 26 is formed by any of the above CVD techniques, preferred is so-called atmospheric CVD whereby film deposition is achieved under a pressure close to atmospheric pressure, say about 90 kPa to 110 kPa.

Use of the atmospheric CVD yields favorable results because it permits reduction of manufacturing costs of the apparatus and is preferable because it permits deposition of the oxide layer 26 with a simple apparatus.

The sputtering techniques that may be used herein may be any known sputtering techniques determined as appropriate including but not limited to magnetron sputtering, reactive sputtering, and RF sputtering.

When the oxide layer 26 is formed by sputtering, it is preferable that the sputtering uses silicon or a silicon compound as target and is accompanied by the introduction of oxygen gas.

Use of such sputtering technique yields favorable results such as remarkably improved gas barrier properties of the gas barrier laminate film over those achieved by vapor deposition.

FIG. 3 is a view showing the concept of an embodiment of the production apparatus for producing the gas barrier laminate film using the production method of the present invention.

In the production apparatus 10 shown in FIG. 3, an organic layer (organic compound layer) 20 is formed on the surface of a long length of substrate Z (film material) that is transported in the longitudinal direction, then a silicon-containing layer (silicon atom-containing compound layer) 24 is formed on the organic layer 20, and subsequently the oxide layer (inorganic compound oxide layer) 26 is formed by a plasma-enhanced CVD technique on the silicon-containing layer 24 to produce a gas barrier film (or material or intermediate product of the gas barrier film), i.e., a gas barrier laminate film as shown in FIG. 1 comprising the organic layer 20, the silicon-containing layer 24, and the oxide layer 26.

This production apparatus 10 is a roll-to-roll type film deposition apparatus whereby the organic compound layer 20, the silicon-containing layer 24, and the oxide layer 26 are sequentially formed on the substrate Z as it is fed from a substrate roll 30, a long length of substrate Z wound into a roll, and transported in a longitudinal direction to produce a gas barrier laminate film, whereupon the substrate Z having the gas barrier laminate film formed thereon, i.e., the gas barrier film, is wound into a roll.

The production apparatus 10 includes a feed chamber 12, a film deposition chamber 14 and a take-up chamber 16.

In addition to the illustrated members, the production apparatus 10 may also have various other members with which film deposition apparatuses that perform film deposition by plasma-enhanced CVD are provided including sensors, and members (transport means) for transporting the substrate Z along a predetermined path, as exemplified by a transport roller pair and guide members for regulating the position in the width direction of the substrate Z.

The feed chamber 12 includes a rotary shaft 32, a guide roller 34 and an evacuation means 35.

The substrate roll 30 into which a long length of substrate Z is wound is mounted on the rotary shaft 32 in the feed chamber 12.

Upon mounting of the substrate roll 30 on the rotary shaft 32, the substrate Z is transported along a predetermined travel path starting from the feed chamber 12 and passing through the film deposition chamber 14 to reach a take-up shaft 36 in the take-up chamber 16.

In the production apparatus 10, feeding of the substrate Z from the substrate roll 30 and winding of the substrate Z on the take-up shaft 36 of the take-up chamber 16 are carried out in synchronism so that the organic layer 20, the silicon-containing layer 24, and the oxide layer 26 are sequentially formed on the long length of substrate Z in the film deposition chamber 14 as the substrate Z travels in its longitudinal direction along the predetermined travel path.

The illustrated production apparatus 10 comprises evacuation means 35 and 106 in the feed chamber 12 and the take-up chamber 16, respectively, as a preferred embodiment. These evacuation means are provided in these chambers to ensure, where necessary, that these chambers have the same degree of vacuum (pressure) during film deposition as the film deposition chamber 14 described later so that the pressures inside these neighboring chambers do not affect the degree of vacuum inside the film deposition chamber 14, i.e., the deposition of the gas barrier film. Where an oxide layer formation section 48 located in the film deposition chamber 14 described later only uses atmospheric CVD technique, the evacuation means 35 and the evacuation means 106 may not be provided.

The evacuation means 35 is not particularly limited, and may be vacuum pumps such as a turbo pump, a mechanical booster pump, a rotary pump and a dry pump, an assist means such as a cryogenic coil, and various other known (vacuum) evacuation means employed in vacuum deposition apparatuses and using means for adjusting the ultimate degree of vacuum or the amount of air discharged. The same applies to the other evacuation means described later.

The present invention is not limited to a configuration wherein all the chambers are provided with evacuation means; the feed chamber 12 and the take-up chamber 16 requiring no evacuation treatment may not be provided with evacuation means. However, in order to minimize the adverse effects of the pressures in these chambers on the degree of vacuum in the film deposition chamber 14, the size of the areas such as the slit 38a through which the substrate Z passes may be reduced to a minimum, or there may be provided between the adjacent chambers a subchamber with a reduced internal pressure.

Also in the illustrated production apparatus 10 in which all the chambers have the evacuation means, it is preferable to minimize the size of the areas, such as the slit 38a, through which the substrate Z passes.

The substrate Z is guided by the guide roller 34 and fed into the film deposition chamber 14 that is separated from the feed chamber 12 by a separation wall 38. As described earlier, the film deposition chamber 14 sequentially forms the organic layer 20, silicon-containing layer 24, and the oxide layer 26 on the substrate Z that is fed and transported.

The film deposition chamber 14 comprises a guide roller 40, an organic layer formation section 42, a silicon-containing layer formation section 46, an oxide layer formation section 48, a guide roller 50, and a drum 52. The organic layer formation section 42 is kept in a substantially air-tight isolation by separation walls 54a and 54b; the silicon-containing layer formation section 46 is kept in a substantially air-tight isolation by separation walls 54b and 54c.

The drum 52 in the film deposition chamber 14 is a cylindrical member that turns about its central axis counterclockwise as seen in the drawing. The substrate Z guided by the guide roller 40 along the predetermined path is passed over a predetermined region of the peripheral surface of the drum 52 and thus held in a predetermined position as it travels in the longitudinal direction to pass the organic layer formation section 42, the silicon-containing layer formation section 46, and the oxide layer formation section 48 sequentially before reaching the guide roller 50.

The drum 52 also serves as a counter-electrode for a shower head electrode 94 in the oxide layer formation section 48, that is, the drum 52 and the shower head electrode 94 form an electrode pair. To this end, the drum 52 is connected to a bias power source or grounded (connection is not shown in either case). Alternatively, the drum 52 may be capable of switching between connection to the bias power source and grounding.

The drum 52 also acts as means for adjusting the temperature of the substrate Z for agglomeration of a sprayed liquid of the organic compound, restriction of increase in temperature of the substrate Z in film deposition process, and the like in the organic layer formation section 42. Thus, the drum 52 contains a built-in temperature adjusting means. The temperature adjusting means of the drum 52 is not particularly limited, and various types of temperature adjusting means may be used including one in which a refrigerant is circulated and a cooling means using a piezoelectric element.

The organic layer formation section 42 forms or deposits the organic layer 20 on the surface of the substrate Z by flash evaporation and comprises an organic layer material evaporation means 58, a curing section 60, an organic layer material supply means 62, and an evacuation means 64.

The evacuation means 64 evacuates the inside of the organic layer formation section 42 so that the pressure in the organic layer formation section 42 matches the flash evaporation effected in the organic layer formation section 42.

The organic layer material supply means 62 evaporates the monomer of a liquid organic compound (or a coating material formed by dissolving the monomer of the organic compound in a solvent), which is a material for forming the organic layer 20, and supplies the organic layer material evaporation means 58 with organic compound vapor thus produced through a pipe 58a.

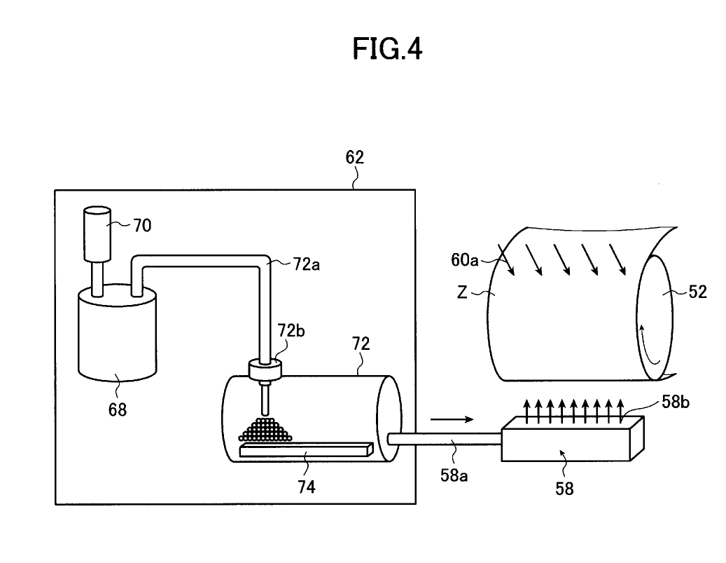

As conceptually shown in FIG. 4, the organic layer material supply means 62 has a liquid organic compound stored therein and is kept under a given reduced pressure. It comprises a tank 68 provided with an evacuation means for reducing the inside of the tank 68 to a given pressure and an agitation means, a syringe pump 70, and a liquid-propelling section (heating chamber) 72 connected with the tank 68 through a pipe 72a.

The liquid organic compound in the tank 68 is agitated by the agitation means under a reduced pressure for defoaming or removal of unnecessary gases. The organic compound is supplied under pressure applied by the syringe pump 70 from the tank 68 to the liquid-propelling section 72. The syringe pump pressure and the liquid supply rate of the syringe pump 70 may be appropriately determined according to such conditions as the thickness of the organic layer 20 and the kind of the organic layer 20 to be formed; preferably, the syringe pump pressure is 50 PSI to 300 PSI, and the liquid supply rate is 0.1 ml/min to 10 ml/min, respectively.

In the illustrated embodiment, the liquid-propelling section 72 has the shape of a hollow cylinder and comprises a heating plate 74 inside. The liquid-propelling section 72 is provided with an evacuation means for evacuating the inside thereof and a heating means for heating the heating plate 74, both not shown.

The liquid-propelling section 72 comprises a droplet injection port 72b at a joint with the pipe 72a. The droplet injection port 72b comprises an ultrasonic wave application means and a cooling means, both not shown.

The liquid organic compound supplied under pressure from the syringe pump 70 to the liquid-propelling section 72 placed under vacuum is reduced to droplets at the droplet injection port 72b to which ultrasonic pressure is applied and sprayed onto the heating plate 74. The power output of the ultrasonic wave used here is not specifically limited and is preferably in a range of 1 W to 10 W to permit reducing the organic compound to a favorable droplet state or for other reasons.

The organic compound in the form of droplets evaporates when it comes into contact with the heating plate 74 to become a vapor. The organic compound now in the form of a vapor is supplied through a pipe 58a to the organic layer material evaporation means 58.

Reduction of the liquid organic compound to fine particles by application of ultrasonic wave increases the evaporation efficiency of the organic compound. The injection port 72b is preferably kept at a temperature in a range of 5° C. to 50° C. by the cooling means to prevent thermal cure of the organic compound due to quick temperature rise of the injection port 72b caused by application of ultrasonic wave thereto.

The heating plate 74 is preferably kept at a temperature in a range of 150° C. to 300° C. for a favorable evaporation efficiency of the liquid organic compound. The liquid-propelling section 72 is preferably kept at a pressure in a range of 2×10⁻³ Pa to 1×10⁻² Pa to ensure efficient supply of the vapor to the organic layer material evaporation section 58.

The organic layer material evaporation means 58 sprays the vapor of the monomer of the organic compound to be formed into the organic layer 20 supplied from the organic layer material supply means 62 onto the surface of the substrate Z passed over the drum 52, allowing the vapor to agglomerate.

It is the differential pressure between the liquid-propelling section 72 and the organic layer formation section 42 that enables the transfer of the vapor from the liquid-propelling section 72 to the organic layer material evaporation means 58 and the spray of the vapor from the organic layer material evaporation means 58.

The organic layer material evaporation means 58 is provided with a heat control means not shown that includes a heating nozzle 58b for heating the environment to a temperature ranging from an agglomeration temperature to an evaporation temperature.

The vapor of the monomer supplied from the organic layer material supply means 62 passes through the heating nozzle 58b and a given amount thereof agglomerates on the substrate Z. The heating nozzle 58b is preferably kept at a temperature of 150° C. to 300° C.

To increase the agglomeration efficiency, the drum 52 is preferably cooled to keep the substrate Z at a temperature of say −15° C. to 25° C.

The curing means 60 cures the organic compound agglomerated on the substrate Z to form it into the organic layer 20. The curing means 60 may be formed using, for example, a UV radiation means for radiating UV light (ultraviolet light) 60a (see FIG. 4). The UV radiation means preferably has a UV illuminance of 10 mW/cm² to 100 mW/cm².

The curing means 60 may be formed using an electron radiation means for radiating electron beams or a microwave radiation means for radiating microwaves.

The silicon-containing layer formation section 46 forms the silicon-containing layer 24 on the surface of the organic layer 20 and comprises a coating means 76, a drying means 78, a curing means 80, a silicon(Si)-containing layer material supply means 90, and a pressure adjusting means 92.

The pressure adjusting means 92 uses a vacuum pump, a pressure adjusting valve, an air supply means, and the like to keep the inside of the silicon-containing layer formation section 46 at an appropriate pressure.

The silicon-containing layer material supply means 90 uses a metering pump, or other like known means to supply the coating means 76 with a coating material that contains a silicon atom-containing compound that is to form the silicon-containing layer 24, e.g., a coating material formed of silsesquioxane described earlier and a binder such as a thermosetting resin or a radiation curable resin dissolved in a solvent.

The coating means 76 uses roll coating, gravure coating, spray coating, or other like known coating means to apply the coating material supplied from the silicon-containing layer material supply means 90 to the surface of the substrate Z (organic layer 20) so that the silicon-containing layer 24 has a given thickness after drying and curing. As described above, the silicon-containing layer 24 is preferably formed by flash evaporation as is the organic layer 20.

The drying means 78 uses heating by a heater, blowing with hot air, or other like known means to dry the coating material applied by the coating means 76.

The curing means 80 irradiates the coating material dried by the drying means 78 with, for example, radiation, electron beams, ultraviolet light, etc. to accomplish polymerization of silsesquioxane described above and other necessary procedures so that the coating material cures and forms the silicon-containing layer 24. Alternatively, heating may be used to achieve polymerization of silsesquioxane described above and other necessary procedures.

The oxide layer formation section 48 forms the oxide layer 26 on the surface of the silicon-containing layer 24 by vapor-phase film deposition.

The inorganic layer formation section 48 in the illustrated embodiment uses a CCP-CVD technique to form (deposit) the oxide layer 26 and comprises a shower head electrode 94, a feed gas supply means 96, an RF power source 98, and an evacuation means 100. Where the oxide layer formation section 48 only uses atmospheric CVD technique, the evacuation means 100 may not be provided.

The shower head electrode 94 is of a known type used in film deposition employing CCP-CVD.

In the illustrated embodiment, the shower head electrode 94 is, for example, in the form of a hollow, substantially rectangular solid and is disposed so that its largest surface faces the peripheral surface of the drum 52 and the perpendicular from the center of the largest surface coincides with the normal to the peripheral surface of the drum 52. A large number of through-holes are formed in the whole surface of the shower head electrode 94 facing the drum 52. In a preferred embodiment, the surface of the shower head electrode 94 facing the drum 52 is so curved as to contour the peripheral surface of the drum 52.

In the illustrated embodiment, one shower head electrode (film deposition means using CCP-CVD) is provided in the oxide layer formation section 48. However, this is not the sole case of the present invention and a plurality of shower head electrodes may be disposed along the path of travel of the substrate Z. The same applies when using other types of plasma-enhanced CVD techniques than CCP-CVD. For example, when a gas barrier film is formed or manufactured by ICP-CVD, a plurality of (induction) coils for forming an induced electric field (induced magnetic field) may be provided along the path of travel of the substrate Z.

According to the invention, the ICP-CVD technique using the shower head electrode 94 is not the only method of forming the inorganic layer 26; other methods that may be used include one employing a common plate electrode and a gas supply nozzle.

The feed gas supply means 96 is of a known type used in vacuum deposition apparatuses such as plasma CVD devices, and supplies a feed gas into the shower head electrode 94. As described above by way of example, an inactive gas, an oxygen gas, and TEOS or HMDSO are supplied as feed gases to the shower head electrode 94.

As described above, a large number of through-holes are formed in the surface of the shower head electrode 94 facing the drum 52. Therefore, the feed gases supplied into the shower head electrode 94 passes through the through-holes and are introduced into the space between the shower head electrode 94 and the drum 52.

The RF power source 98 is provided to supply plasma excitation power to the shower head electrode 94. The RF power source 98 may be any of known RF power sources used in various plasma CVD devices.

In addition, the evacuation means 100 evacuates the oxide layer formation section 48, i.e., the closed space defined by the separation wall 54a, the separation wall 54c, and the peripheral surface of the drum 52, to keep it at a predetermined film deposition pressure in order to form the gas barrier layer by plasma-enhanced CVD. Where the oxide layer formation section 48 only uses atmospheric CVD technique, the evacuation means 100 may not be provided as mentioned above.

The substrate Z passed over the drum 52 travels in the longitudinal direction to sequentially undergo formation of the organic layer 20 in the organic layer formation section 42, formation of silicon-containing layer 24 in the silicon-containing layer formation section 46, and formation of the oxide layer 26 in the oxide layer formation section 48 before being guided by the guide roller 50 to enter the take-up chamber 16.

Now, the present invention will be described in more detail by describing the formation of the gas barrier laminate film in the film deposition chamber 14.

As described above, upon mounting of the substrate roll 30 on the rotary shaft 32, the substrate Z is reeled out from the substrate roll 30 to travel along the predetermined travel path as it is guided by the guide roller 34 to reach the film deposition chamber 14, where the substrate Z is guided by the guide roller 40, passed over a predetermined region of the peripheral surface of the drum 52 and guided by the guide roller 50 to reach the take-up chamber 16, where the substrate Z is guided by a guide roller 104 to reach the take-up shaft 36.

The substrate Z fed from the feed chamber 12 and guided by the guide roller 40 along the predetermined path travels on the predetermined travel path as it is supported/guided by the drum 52.

The organic layer formation section 42 is reduced by the evacuation means 64 to a given degree of vacuum matching the formation of the organic layer 20 by flash evaporation, the silicon-containing layer formation section 46 is reduced by the pressure adjusting means 92 to a given degree of vacuum matching the formation of the silicon-containing layer 24, and the oxide layer formation section 48 is reduced by the evacuation means 100 to a given degree of vacuum matching the formation of the oxide layer 26. The feed chamber 12 is reduced by the evacuation means 35 to a given degree of vacuum; the take-up chamber 16 is reduced by the evacuation means 106 to a given degree of vacuum.

The shower head electrode 94 in the oxide layer formation section 48 is supplied with a feed gas matching the oxide layer 26 to be formed from the feed gas supply means 96.

When the supply amount of the feed gas and the pressures inside the formation sections have stabilized, the following processes are sequentially accomplished in the respective sections: spray of the organic compound vapor, which is to be formed into the organic layer 20, by the organic layer material supply means 62 to the organic layer material evaporation means 58 (heating nozzle 58b) and radiation of UV light by the curing means 60 in the organic layer formation section 42; supply of a coating material from the silicon-containing layer material supply means 90 to the coating means 76, application of the coating material by the coating means 76, actuation of the drying means 78 and the curing means 80 in the silicon-containing layer formation section 46; and supply of plasma excitation power from the RF power source 98 to the shower head electrode 94 in the oxide layer formation section 48.

Thus, the surface of the substrate Z fed and passed over the drum 52 is sequentially formed with the organic layer 20 in the organic layer formation section 42, the silicon-containing layer 24 in the silicon-containing layer formation section 46, and the oxide layer 26 in the oxide layer formation section 48 to achieve formation of the gas barrier laminate film of the invention by the production method according to the invention.

The substrate Z, now formed with the gas barrier laminate film composed of the organic layer 20, silicon-containing layer 24, and the oxide layer 26, is guided through the guide roller 50 and admitted through a slit 102a into the take-up chamber 16 that is separated from the film deposition chamber 14 by a separation wall 102. In the illustrated embodiment, the take-up chamber 16 includes the guide roller 104, the take-up shaft 36 and the evacuation means 106.

The substrate Z formed with the gas barrier laminate film and admitted in the take-up chamber 16 is guided to the take-up shaft 36, whereby the substrate Z is wound into a roll and supplied as an intermediate product of gas barrier film, for example, to a next step.

The take-up chamber 16 is also provided with the evacuation means 106 as in the above-described feed chamber 12, and during formation of the gas barrier laminate film, the pressure inside the take-up chamber 16 is reduced to a degree of vacuum suitable for the film deposition pressure in the film deposition chamber 14.

The above-described embodiment exemplifies a case where the method of producing the gas barrier laminate film according to the present invention is applied to a roll-to-roll type apparatus. However, this is not the sole case of the present invention and as described above, the gas barrier laminate film may be formed on substrate sheets, optical devices such as lenses and displays, and solar cells. Thus, the present invention may be used for a so-called batch type production of a gas barrier laminate film.

While the gas barrier laminate film of the invention and the method for producing the gas barrier laminate film according to the invention have been described above in detail, the present invention is by no means limited to the foregoing embodiments and various improvements and modifications may of course be made without departing from the gist of the present invention.

### EXAMPLES

Next, the present invention is described in further detail by referring to the Examples.

### Example 1

The substrate Z used was a 100 μm-thick Q65FA, a PEN film provided by Teijin DuPont Films Japan Limited.

A coating material was formulated using 7 wt % of acrylate monomer (DPHA provided by DAICEL-CYTEC COMPANY LTD.), 1 wt % of photopolymerization initiator (IRGACURE-907 provided by Ciba Inc.), and 92 wt % of organic solvent (PGMEA or propylene glycol monomethyl ether acetate).

The coating material thus formulated was applied to the substrate Z by spin coating and dried. Then, the dried coating material was irradiated with ultraviolet light to form the organic layer 20 on the substrate Z. The organic layer 20 had a thickness of 0.6 μm.

Another coating material was formulated using 7 wt % of polysilsesquioxane monomer having acryl group (AC-SQ provided by Toagosei Co., Ltd.), 1 wt % of photopolymerization initiator (IRGACURE-907 provided by Chiba Japan), and 92 wt % of organic solvent (PGMEA).

The coating material thus formulated was applied by spin coating to the surface of the organic layer 20 formed on the substrate Z and dried. Then, the dried coating material was irradiated with ultraviolet light to form the silicon-containing layer 24. The silicon-containing layer 24 had a thickness of 0.2 μm.

Further, a 0.1 μm-thick SiOₓ film was formed as the oxide layer 26 by atmospheric barrier discharge DVD on the surface of the silicon-containing layer 24 formed on the organic layer 20 to produce a gas barrier film or a gas barrier laminate film formed of the organic layer 20, the silicon-containing layer 24, and the oxide layer 26.

The feed gas used was TEOS. The flow rate was 2 g/hr. The carrier gases used were nitrogen gas (flow rate 20 slm), oxygen gas (flow rate 0.5 slm), and argon gas (flow rate 0.1 slm). The pressure for film formation was set to 100 kPa.

The plasma excitation power used was set to a frequency of 150 kHZ, 500 W for use.

### Example 2

A gas barrier film was produced in exactly the same manner as in Example 1 except that the oxide layer 26 was a 0.05 μm thick SiOₓ film formed by RF sputtering.

The target used was silicon. The carrier gases used were oxygen gas (flow rate 50 sccm) and argon gas (flow rate 140 sccm).

The plasma excitation power used was set to a frequency of 13.56 MHZ, 2000 W for use. The pressure for film formation was set to 0.2 Pa.

### Example 3

A gas barrier film was produced in exactly the same manner as in Example 1 except that the silicon-containing layer 24 was a 0.05 μm thick SiOC film.

The SiOC film was formed by mixing TEOS fed at a flow rate of 0.1 g/hr with a carrier gas composed of nitrogen gas fed at a flow rate of 20 slm, oxygen gas fed at a flow rate of 0.5 slm, and argon gas fed at a flow rate of 0.1 slm and blowing the mixed gases thus prepared onto the surface of the organic layer 20.

### Example 4

A gas barrier film was produced in exactly the same manner as in Example 1 except that the silicon-containing layer 24 was a 0.05 μm thick PHPS film (perhydropolysilazane).

The silicon-containing layer 24 was formed as follows. Five wt % of PHPS was dissolved in 95 wt % xylene to prepare a coating material, which was applied by spin coating to the surface of the organic layer 20 and dried. Then, the dried coating material was thermally cured at 80° C. for 15 min to form the silicon-containing layer 24.

### Comparative Example 1

A gas barrier laminate film was produced in exactly the same manner as in Example 1 except that the silicon-containing layer 24 was not formed. Thus, the gas barrier laminate film formed had a dual-layer structure composed of the organic layer 20 and the oxide layer 26.

### Comparative Example 2

A gas barrier film was produced in exactly the same manner as in Example 1 except that the silicon-containing layer 24 was not formed and the organic layer 20 was a 0.6-μm thick DPCA film.

The DPCA film was formed as follows. A coating material was formulated using 7 wt % of acrylate monomer (DPCA provided by DAICEL-CYTEC COMPANY LTD.), 1 wt % of photopolymerization initiator (IRGACURE-907 provided by Ciba Inc.), and 92 wt % of organic solvent (PGMEA). The coating material thus formulated was applied to the substrate Z by spin coating and dried. Then, the dried coating material was irradiated with ultraviolet light to form the organic layer 20.

### Comparative Example 3

A gas barrier film was produced in exactly the same manner as in Example 1 except that the silicon-containing layer 24 was not formed and the oxide layer 26 was a 0.05 μm thick AlₓO_{y} film.

The oxide layer 26 was formed by magnetron sputtering using argon gas and oxygen gas as carrier gas, with an aluminum target. The flow rate of argon gas was 140 sccm, the flow rate of oxygen gas was 50 sccm, and the plasma excitation power was 2000 W. The pressure for film formation was set to 0.4 Pa.

### Comparative Example 4

A gas barrier film was produced in exactly the same manner as in Example 1 except that a 0.05 μm thick SiNₓ layer was formed by low-pressure CCP-CVD in lieu of the oxide layer 26.

The feed gases used were silane gas (flow rate 250 sccm), ammonia gas (flow rate 500 sccm), and nitrogen gas (flow rate 500 sccm); the film deposition pressure was 40 Pa; the plasma excitation power was set to a frequency of 13.56 MHz, 2000 W.

The eight different gas barrier films thus produced were examined for gas barrier properties and safety to evaluate their performances.

### Gas Barrier Properties

The moisture vapor transmission rate [g/(m²·day)] of the gas barrier films was measured by the calcium corrosion method (a method described in JP 2005-283561 A).

Gas barrier films having a moisture vapor transmission rate of 1.0×10⁻¹ or more were rated poor;

gas barrier films having a moisture vapor transmission rate of 1.0×10⁻³ inclusive to 1.0×10⁻¹ exclusive were rated fair; and

gas barrier films having a moisture vapor transmission rate of less than 1.0×10⁻³ were rated good.

### Safety

Gas barrier films were rated good where all the layers were formed using only those gases for which installation of an abatement system is not mandatory according to General High-pressure Gas Safety Regulations;

Gas barrier films were rated poor where at least one of the layers were formed using a gas for which installation of an abatement system is mandatory according to General High-pressure Gas Safety Regulations.

### Performance Ratings

Gas barrier films having gas barrier properties and safety both rated good were rated good;

gas barrier films having gas barrier properties rated fair and safety rated good were rated fair; and

gas barrier films having either gas barrier properties or safety rated poor were rated poor;

The results are shown in Table 1.

TABLE 1

| | | Gas | | |
|---|---|---|---|---|
| | | barrier | | |
| | Layer Configuration | properties | Safety | Ratings |
| Example 1 | DPHA/Silsesquioxane/SiO | Good | Good | Good |
| Example 1 | DPHA/silsesquioxane/SiO | Good | Good | Good |
| Example 3 | DPHA/SiOC/SiO | Good | Good | Good |
| Example 4 | DPHA/PHPS/SiO | Good | Good | Good |
| Comp. Ex. 1 | DPHA/SiO | Poor | Good | Poor |
| Comp. Ex. 2 | DPCA/SiO | Poor | Good | Poor |
| Comp. Ex. 3 | DPHA/AlO | Poor | Good | Poor |
| Comp. Ex. 4 | DPHA/Silsesquioxane/SiN | Good | Poor | Poor |

As shown in the above table, all the gas barrier films (gas barrier laminate films) comprising the organic layer 20, the silicon-containing layer 24, and the oxide layer 26 formed according to the invention have excellent gas barrier properties and a high degree of safety.

In comparison, any of Comparative Examples 1 to 3 without the silicon-containing layer 24 fails to provide sufficient gas barrier properties. While Comparative Example 4, formed with a SiNₓ film in lieu of the oxide layer 26, has good gas barrier properties, it involves danger in manufacturing owing to silane gas used as feed gas.

The above results clearly show the beneficial effects of the present invention.

Thus, the invention may be favorably used for the manufacture of various products involving inorganic/organic gas barrier laminate films, wherein manufacturing safety is required in addition to high gas barrier properties to be achieved.

What is claimed is:

1. A gas barrier laminate film comprising at least one combination of a 0.1 μm to 3 μm thick organic compound layer, a 0.005 μm to 0.3 μm thick silicon atom-containing compound layer formed on the organic compound layer, and an inorganic compound oxide layer formed on the silicon atom-containing compound layer.

2. The gas barrier laminate film according to claim 1, wherein the silicon atom-containing compound layer contains polysilsesquioxane.

3. The gas barrier laminate film according to claim 2, wherein the polysilsesquioxane contains (meth)acryl group.

4. The gas barrier laminate film according to claim 2, wherein the polysilsesquioxane comprises one or more of a cage structure, a ladder structure, a random structure, and a cleaved structure.

5. The gas barrier laminate film according to claim 1, wherein the silicon atom-containing compound layer contains a compound expressed by SiOₓ and contains 10% or less of impurities by atomic composition.

6. A method of producing a gas barrier laminate film, comprising:
forming a 0.1 μm to 3 μm thick organic compound layer on a substrate,
forming a 0.005 μm to 0.3 μm thick silicon atom-containing compound layer on the organic compound layer, and
forming an inorganic compound oxide layer on the silicon atom-containing compound layer.

7. The method of producing a gas barrier laminate film according to claim 6, wherein the silicon atom-containing compound layer contains polysilsesquioxane.

8. The method of producing a gas barrier laminate film according to claim 6, wherein the silicon atom-containing compound layer contains a compound expressed by SiOₓ and contains 10% or less of impurities by atomic composition.

9. The method of producing a gas barrier laminate film according to claim 6, wherein the inorganic compound oxide layer is formed by CVD using at least an inactive gas, oxygen gas, and tetraethoxysilane or hexamethyldisiloxane as feed gases.

10. The method of producing a gas barrier laminate film according to claim 9, wherein the CVD is atmospheric CVD.

11. The method of producing a gas barrier laminate film according to claim 6, wherein the inorganic compound oxide layer is formed by sputtering using a target formed of silicon or a silicon compound and accompanied by introduction of oxygen gas.

12. The method of producing a gas barrier laminate film according to claim 6, wherein the silicon atom-containing compound layer is formed by applying a liquid containing a silicon atom-containing compound onto the organic compound layer and curing the silicon atom-containing compound by one or more of irradiation with ultraviolet light, exposure to radiation, and heating.

13. The method of producing a gas barrier laminate film according to claim 6, wherein a long length of substrate is passed over a peripheral surface of a cylindrical drum and transported in a longitudinal direction,
the method comprising, sequentially,
forming the organic compound layer by using an organic compound layer forming means provided opposite the peripheral surface of the drum,
forming the silicon atom-containing compound layer by using a silicon atom-containing compound layer forming means provided downstream of the organic compound layer forming means, and
forming the inorganic compound oxide layer by using a film deposition means provided downstream of the silicon atom-containing compound layer forming means employing vapor-phase film deposition technique.

14. The method of producing a gas barrier laminate film according to claim 6, wherein the organic compound layer is formed by flash evaporation.
